(19) United States
(12) Patent Application Publication
(10) Pub. No.: US 2026/0068665 A1
(43) Pub. Date: Mar. 5, 2026

(54) SEMICONDUCTOR DEVICE

(71) Applicant: Samsung Electronics Co., Ltd., Suwon-si (KR)

(72) Inventors: Jeewoong Kim, Suwon-si (KR); Kyoungwoo Lee, Suwon-si (KR); Yunsuk Nam, Suwon-si (KR); Hidenobu Fukutome, Suwon-si (KR); Jinkyu Kim, Suwon-si (KR)

(21) Appl. No.: 19/056,560

(22) Filed: Feb. 18, 2025

(30) Foreign Application Priority Data
Sep. 2, 2024 (KR) 10-2024-0118558

(51) Int. Cl. H01L 23/373; H01L 23/00; H10D 30/00

(52) U.S. Cl. CPC H01L 23/3735; H10D 30/501

(57) ABSTRACT

A semiconductor device includes a semiconductor element portion that includes a semiconductor element, a first wiring portion that is on a first surface of the semiconductor element portion, a support substrate that is on the first wiring portion, a bonding layer that is between the first wiring portion and the support substrate, and a second wiring portion that is on a second surface of the semiconductor element portion opposite to the first surface of the semiconductor element portion. The bonding layer includes a pattern layer. The pattern layer includes a first pattern that includes an insulating material and a second pattern that has a thermal conductivity greater than a thermal conductivity of the first pattern and is electrically insulated from the first wiring portion.

### CROSS-REFERENCE TO RELATED APPLICATION

This application claims priority to and the benefit of Korean Patent Application No. 10-2024-0118558 filed in the Korean Intellectual Property Office on Sep. 2, 2024, the entire contents of which are incorporated herein by reference.

### TECHNICAL FIELD

The present disclosure relates to a semiconductor device, and more particularly, a semiconductor device having an improved structure.

### BACKGROUND

A semiconductor device may have a small size while performing various functions, and is thus widely used in various electronic industries. As advancements are made in the electronic industry, research is continuing to enhance various properties such as speed, function, reliability, and an integration degree.

Heat is generated when a semiconductor device operates. If the heat is not discharged or dissipated sufficiently, performance of the semiconductor device may be deteriorated or inhibited. As the integration degree of the semiconductor device increases, more heat is generated in the semiconductor device, which may lead to greater degradation in the performance of the semiconductor device. Accordingly, research is continuing to sufficiently dissipate the heat generated when the semiconductor device operates.

### SUMMARY

The present disclosure provides a semiconductor device capable of enhancing performance and reliability.

A semiconductor device according to an embodiment includes a semiconductor element portion that includes a semiconductor element, a first wiring portion that is on a first surface of the semiconductor element portion, a support substrate that is on the first wiring portion, a bonding layer that is between the first wiring portion and the support substrate, and a second wiring portion that is on a second surface of the semiconductor element portion opposite to the first surface of the semiconductor element portion. The bonding layer includes a pattern layer. The pattern layer includes a first pattern that includes an insulating material and a second pattern that has a thermal conductivity greater than a thermal conductivity of the first pattern and is electrically insulated from the first wiring portion.

A semiconductor device according to an embodiment includes a semiconductor element portion that includes a semiconductor element, a first wiring portion that is on a first surface of the semiconductor element portion, a support substrate that is on the first wiring portion, a bonding layer that is between the first wiring portion and the support substrate, and a second wiring portion that is on a second surface of the semiconductor element portion opposite to the first surface of the semiconductor element portion. The bonding layer includes a first insulation layer that is on the first wiring portion and a conductive pattern that is on the first insulation layer.

A semiconductor device according to an embodiment includes a semiconductor element portion that includes a semiconductor element, a front wiring portion that is on a front surface of the semiconductor element portion, a support substrate that is on the front wiring portion, an intermediate layer that is between the front wiring portion and the support substrate, and a rear wiring portion that is on a rear surface of the semiconductor element portion. The intermediate layer includes a pattern layer. The pattern layer includes an insulation pattern that includes an insulating material and a heat dissipation pattern that includes a conductive material and is electrically insulated from the front wiring portion.

According to an embodiment, an intermediate layer between a first wiring portion and a support substrate (e.g., a bonding layer configured to bond the first wiring portion and the support substrate) may include a heat dissipation pattern (e.g., a second pattern), thereby improving effective thermal conductivity of the intermediate layer (e.g., the bonding layer) and forming a heat dissipation path toward the support substrate. Accordingly, a heat dissipation property of a semiconductor device may be enhanced. Since the heat dissipation pattern (e.g., the second pattern) may be electrically insulated from the first wiring portion, the heat dissipation property may be enhanced without increasing a wiring path and electrical resistance of a wiring. Thereby, the performance and reliability of the semiconductor device may be enhanced.

### BRIEF DESCRIPTION OF THE DRAWINGS

FIG. 1 is a cross-sectional view that illustrates a semiconductor device according to an embodiment.

FIG. 2 is an enlarged cross-sectional view of a portion A in FIG. 1.

FIG. 3 is a plan view that illustrates a partial portion of a pattern layer of a bonding layer included in the semiconductor device illustrated in FIG. 1.

FIG. 4 to FIG. 12 are cross-sectional views that illustrate a manufacturing method of a semiconductor device according to an embodiment.

FIG. 13 is a cross-sectional view that illustrates a partial portion of a semiconductor device according to another embodiment.

FIG. 14 is a cross-sectional view that illustrates a partial portion of a semiconductor device according to another embodiment.

FIG. 15 is a plan view that illustrates a partial portion of a pattern layer of a bonding layer included in a semiconductor device according to another embodiment.

FIG. 16 is a plan view that illustrates a partial portion of a pattern layer of a bonding layer included in a semiconductor device according to another embodiment.

FIG. 17 is a plan view that illustrates a partial portion of a pattern layer of a bonding layer included in a semiconductor device according to another embodiment.

FIG. 18 is a cross-sectional view that illustrates a partial portion of a semiconductor device according to an embodiment.

FIG. 19 is a cross-sectional view that illustrates a partial portion of a semiconductor device according to another embodiment.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in various different forms and is not limited to the embodiment provided herein.

A portion unrelated to the description is omitted in order to clearly describe the present disclosure, and same or similar components are denoted by a same reference numeral throughout the present specification.

Further, since a size and/or a thickness of a portion, a region, a member, a unit, a layer, a film, a substrate, or so on illustrated in the accompanying drawings may be arbitrarily illustrated for better understanding and convenience of explanation, the present disclosure is not limited to the illustrated size and/or thickness. In the drawings, a thickness of a portion, a region, a member, a unit, a layer, a film, a substrate, or so on may be enlarged or exaggerated for convenience of explanation and/or simple illustration

It will be understood that when a component such as a portion, a region, a member, a unit, a layer, a film, a substrate, or so on is referred to as being “on” another component, it may be directly on another component or an intervening component may also be present. In contrast, when a component is referred to as being “directly on” another component, there is no intervening component present. Further, when a component is referred to as being “on” or “above” a reference component, a component may be disposed on or below the reference component, and does not necessarily be “on” or “above” the reference component toward an opposite direction of gravity.

In addition, throughout the specification, unless explicitly described to the contrary, the word “comprise”, “include”, or “contain”, and variations such as “comprises”, “comprising”, “includes”, “including”, “contains” or “containing” will be understood to imply the inclusion of other components rather than the exclusion of any other components. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

Further, throughout the specification, a phrase “on a plane”, “in a plane”, “on a plan view”, or “in a plan view” may indicate a case where a portion is viewed from above or a top portion, and a phrase “on a cross-section” or “in a cross-sectional view” may indicate a case where a cross-section taken along a vertical direction is viewed from a side.

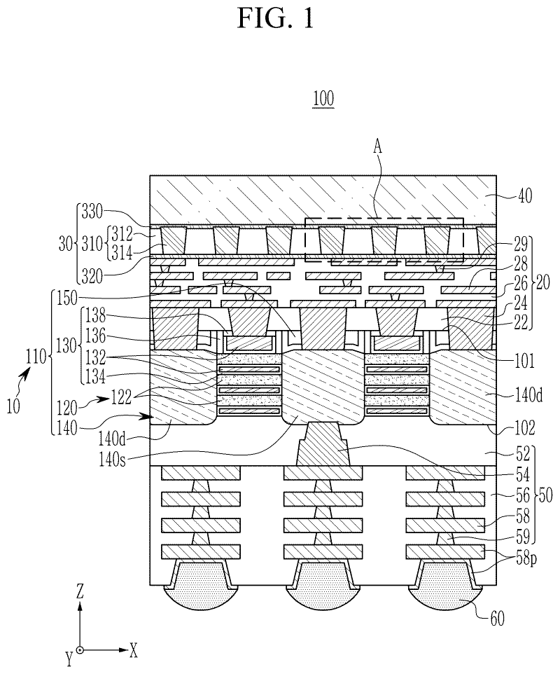

Hereinafter, referring to FIG. 1 to FIG. 12, a semiconductor device according to an embodiment and a manufacturing method of the same will be described in detail.

FIG. 1 is a cross-sectional view that illustrates a semiconductor device 100 according to an embodiment.

Referring to FIG. 1, a semiconductor device 100 according to an embodiment may include a semiconductor element portion 10, a first wiring portion 20, a support substrate 40, an intermediate layer (e.g., a bonding layer 30), and a second wiring portion 50. The semiconductor element portion 10 may include a semiconductor element 110. The first wiring portion 20 may be disposed on a first surface 101 of the semiconductor element portion 10. The support substrate 40 may be disposed on the first wiring portion 20. The intermediate layer (e.g., the bonding layer 30) may be disposed between the first wiring portion 20 and the support substrate 40. The second wiring portion 50 may be disposed on a second surface 102 of the semiconductor element portion 10 that is opposite to the first surface 101 of the semiconductor element portion 10. The semiconductor device 100 according to an embodiment may further include a connection bump 60 that is electrically connected to the second wiring portion 50.

For example, the first surface 101 of the semiconductor element portion 10 may be a front surface or an upper surface of the semiconductor element portion 10, and the second surface 102 of the semiconductor element portion 10 may be a rear surface or a lower surface of the semiconductor element portion 10. The first wiring portion 20 may be referred to as a front wiring portion, and the second wiring portion 50 may be referred to as a rear wiring portion.

In an embodiment, the semiconductor element portion 10 may include any of various semiconductor elements 110. In FIG. 1 and its description, it is illustrated and described as an example that the semiconductor element 110 is a transistor and the semiconductor element portion 10 includes the transistor. In an embodiment, a plurality of semiconductor elements 110 (e.g., a plurality of transistors) may be included, and the plurality of semiconductor elements 110 (e.g., the plurality of transistors) may form various logic elements, such as an AND element, an OR elements, a NOR elements, an inverter, or so on, alone or in combination with other elements.

However, the embodiments are not limited thereto. The semiconductor element 110 may include not only an active element (such as the transistor) but also a passive element such as a capacitor, a resistor, an inductor, or so on. In some embodiments, the semiconductor element 110 that is included in the semiconductor element portion 10 may form an element other than the logic element. Various other modifications are possible.

In an embodiment, the semiconductor element 110 of the transistor may have any of various structures. For example, the semiconductor element 110 may be a field effect transistor (FET) with a three-dimensional structure that has a fin structure, a gate-all-around (GAA) structure, or a multi-bridge-channel (MBC) structure, or so on. When the semiconductor element 110 may have the three-dimensional structure, a leakage current may be reduced and excellent performance may be achieved. However, the embodiments are not limited thereto, and the semiconductor element 110 may be formed of a transistor with a structure other than the above structure.

For example, the semiconductor element 110 may include an active region 120, a gate structure 130, source and drain patterns 140, and an upper insulation layer 150.

The active region 120 may include a semiconductor layer, a semiconductor region, and/or a semiconductor substrate that includes or is formed of a semiconductor material. A portion of the active region 120 that overlaps the gate structure 130 may form a channel region of the semiconductor element 110.

In an embodiment, the active region 120 may include a plurality of channel layers 122. The plurality of channel layers 122 may be spaced apart from each other in a thickness direction of the semiconductor device 100 (a Z-axis direction in the drawings). For example, the thickness direction may be perpendicular to a first surface of the support substrate 40. The plurality of channel layers 122 may be spaced apart from each other with a regular interval in a first direction (an X-axis direction in the drawings) and a second direction (a Y-axis direction in the drawings). For example, the first direction and/or the second direction may be parallel to the first surface of the support substrate 40.

Each of the plurality of channel layers 122 may include a channel pattern with a nanosheet shape that has a thickness of a nanometer level (e.g., less than 1 μm, for example, 1 nm to 10 nm). The channel pattern of the channel layer 122 may be a semiconductor pattern that includes or is formed of a semiconductor material. However, the embodiments are not limited thereto, and shapes of the plurality of channel layers 122 may be variously modified, and/or the thickness of the channel layer 122 may be less than 1 nm or may be greater than 10 nm.

The channel layer 122 may include an epitaxial layer that includes or is formed of a semiconductor material. For example, the channel layer 122 may include or be formed of at least one of a group IV semiconductor, a group III-V compound semiconductor, or a group II-VI compound semiconductor. For example, the channel layer 122 may include or be formed of at least one of Si, Ge, SiGe, SiC, GaAs, InAs, or InP, for example, Si, Ge, or SiGe.

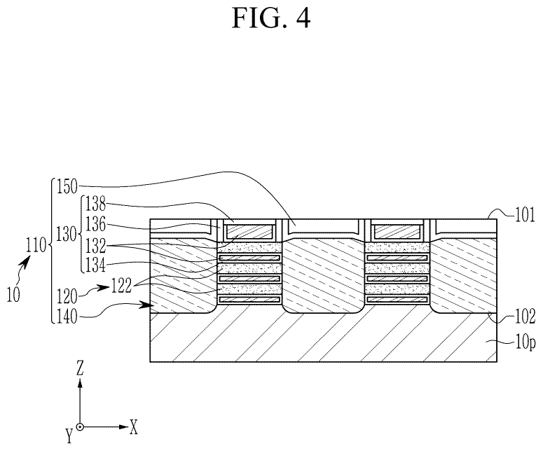

In FIG. 1, it is illustrated as an example that the active region 120 includes the plurality of channel layers 122. In some embodiments, the active region 120 may further include a lower pattern. The lower pattern may be disposed at a lower portion of the plurality of channel layers 122 that is adjacent to the second wiring portion 50. In a process of removing at least a partial portion of a semiconductor substrate 10p (refer to FIG. 4), a partial portion of the semiconductor substrate 10p may remain to form the lower pattern. A plurality of lower patterns may be spaced apart from each other with a regular interval in the first direction (the X-axis direction in the drawings). The lower pattern may have a shape of longitudinally extending in the second direction (the Y-axis direction in the drawings), or may include a plurality of portions that are spaced apart from each other with a regular interval in the second direction. The lower pattern may include a material same as a material of the channel layer 122, or may include a material different from the material of the channel layer 122.

In an embodiment, a shape or a material of a portion (e.g., the channel layer 122 or the lower pattern) that is included in the active region 120, a number of the channel layer 122, or so on may be variously modified.

The gate structure 130 may be disposed on the active region 120. The gate structure 130 may extend in the second direction (the Y-axis direction in the drawings). A plurality of gate structures 130 may be spaced apart from each other in the first direction (the X-axis direction in the drawings).

The gate structure 130 may include a gate electrode 132, a gate insulation layer 134, a gate spacer 136, and a gate capping layer 138.

The gate electrode 132 may entirely (or at least partially) surround each of the plurality of channel layers 122, and may be disposed on the active region 120 that includes the plurality of channel layers 122. The gate electrode 132 may extend in the second direction (the Y-axis direction in the drawings). In some embodiments, a gate separation portion may be included so that the gate electrode 132 includes a plurality of portions spaced apart from each other in the second direction.

The gate insulation layer 134 may be disposed between the gate electrode 132 and the channel layer 122. Between the plurality of channel layers 122, the gate insulation layer 134 may be disposed on an upper surface, a lower surface, and both surfaces in the first direction (the X-axis direction in the drawings) of the gate electrode 132. On the active region 120 that includes the plurality of channel layers 122, the gate insulation layer 134 may include a portion disposed between the active region 120 and the gate electrode 132, and a portion disposed between the gate electrode 132 and the gate spacer 136.

In some embodiments, between the plurality of channel layers 122, inner spacers may be disposed between a portion where the gate electrode 132 and the gate insulation layer 134 are disposed and the source and drain patterns 140. The inner spacer may include or be formed of an insulating material. The inner spacer may include a same material as a material of the gate spacer 136, or may include a material different from the material of the gate spacer 136.

On the active region 120, the gate spacer 136 may be disposed on a side surface of the gate electrode 132. For example, on the active region 120, the gate spacer 136 may be disposed on the gate insulation layer 134 on the side surface of the gate electrode 132. The gate spacer 136 may electrically insulate the gate electrode 132 and the source and drain patterns 140 and/or may electrically insulate the gate electrode 132 and a first connection contact portion 24. The gate spacer 136 may extend in the second direction (the Y-axis direction in the drawings) at both side surfaces of the gate electrode 132 in the first direction (the X-axis direction in the drawings).

The gate capping layer 138 may be disposed on an upper surface of the gate electrode 132 that is disposed on the active region 120. In FIG. 1, it is illustrated as an example that the gate spacer 136 is disposed on a side surface of the gate capping layer 138, but the embodiments are not limited thereto. In some embodiments, the gate capping layer 138 may be disposed on the gate spacer 136. In an embodiment, an upper surface of the gate capping layer 138 may be disposed on a same plane as an upper surface of the upper insulation layer 150 (e.g., the upper surface of the gate capping layer 138 and the upper surface of the upper insulation layer 150 are coplanar). However, the embodiments are not limited thereto, and the upper surface of the gate capping layer 138 may be disposed on a plane different from the upper surface of the upper insulation layer 150.

The gate electrode 132 may include or be formed of a conductive material. For example, the gate electrode 132 may include or be formed of at least one of metal, a metal alloy, metal nitride, metal silicide, or a doped semiconductor material. The metal, the metal alloy, the metal nitride, or the metal silicide that is included in the gate electrode 132 may include or be formed of at least one of copper, aluminum, tungsten, molybdenum, titanium, tantalum, nickel, gold, tin, manganese, or cobalt. The doped semiconductor material may be doped with an n-type dopant or a p-type dopant. For example, the doped semiconductor material may be a polycrystalline semiconductor material doped with an n-type dopant or a p-type dopant. The gate electrode 132 may further include metal oxide or metal oxynitride in which the above material is oxidized. The gate electrode 132 may include a single layer or may include a plurality of electrode layers.

The gate insulation layer 134 may include or be formed of oxide, nitride, or a high dielectric constant material. The high dielectric constant material may be a dielectric material having a dielectric constant higher than a dielectric constant of silicon oxide (SiOx). For example, the gate insulation layer 134 may include or be formed of at least one of silicon oxide (SiOx), silicon nitride (SiNx), silicon oxynitride (SiONx), hafnium oxide (HfOx), aluminum oxide (AlOx), or tantalum oxide (TaOx). The gate insulation layer 134 may include a single layer or may include a plurality of insulation layers.

The gate spacer 136 may include or be formed of at least one of silicon oxide (SiOx), silicon nitride (SiNx), or silicon oxynitride (SiONx), or a material that include the above material and carbon. For example, the gate spacer 136 may include or be formed of a low dielectric constant material. The gate spacer 136 may include a single layer or may include a plurality of layers. The gate capping layer 138 may include or be formed of at least one of silicon oxide (SiOx), silicon nitride (SiNx), silicon oxynitride (SiONx), silicon carbonitride (SiCNx), or silicon oxycarbonitride (SiOCNx). The gate capping layer 138 may include a single layer or may include a plurality of layers.

However, the embodiments are not limited thereto, and the gate electrode 132, the gate insulation layer 134, the gate spacer 136, or the gate capping layer 138 may have any of various structures, or may include or be formed of any of various materials.

The source and drain patterns 140 may be disposed at both sides the active region 120 and/or the gate structure 130. For example, the source and drain patterns 140 may be disposed to be adjacent to both sides of the active region 120 in the first direction (the X-axis direction in the drawings). The source and drain patterns 140 may form source and drain regions of the semiconductor element 110.

The source and drain patterns 140 may include or be formed of an epitaxial layer formed through a selective epitaxial growth (SEG) process at a portion where a portion of the active region 120 is removed. The source and drain patterns 140 may have an angular shape, but the embodiments are not limited thereto. The source and drain patterns 140 may have any of various shapes such as a polygonal shape, a circular shape, an oval shape, or a rounded shape.

For example, the source and drain patterns 140 may include or be formed of at least one of Si, Si—Ge, or SiC, and may further include a dopant such as arsenic (As) or phosphorus (P). In some embodiments, the source and drain patterns 140 may include a plurality of portions having different materials or different compositions. However, the embodiments are not limited thereto, and the source and drain patterns 140 may include any of various materials or have any of various structures.

The upper insulation layer 150 may cover or be on the source and drain patterns 140 outside the gate spacer 136. At least a portion of the upper insulation layer 150 may be formed before a process of forming the source and drain patterns 140, and the source and drain patterns 140 may be grown and formed in a space defined by the upper insulation layer 150. However, the embodiments are not limited thereto, and a manufacturing order of the source and drain patterns 140 and the upper insulation layer 150 may be variously modified.

For example, the upper insulation layer 150 may include or be formed of at least one of silicon oxide (SiOx), silicon nitride (SiNx), silicon oxynitride (SiONx), or a low dielectric constant material. However, the embodiments are not limited thereto, and the upper insulation layer 150 may include any of various materials. The upper insulation layer 150 may include a single layer or may include a plurality of layers. In an embodiment, an etching stopping layer may be further disposed between the source and drain patterns 140 and the upper insulation layer 150. In an embodiment, at least a partial portion of the upper insulation layer 150 may be formed of a front insulation layer 22.

The first wiring portion 20 may be disposed on the first surface 101 of the semiconductor element portion 10. For example, the first wiring portion 20 may be disposed on the gate structure 130 and the upper insulation layer 150 that is disposed on the source and drain patterns 140. The first wiring portion 20 may be a signal wiring portion that is disposed on the first surface 101 of the semiconductor element portion 10 and transmits signals to the semiconductor element 110.

The first wiring portion 20 may include a front insulation layer 22, a first connection contact portion 24, a first interlayer insulation layer 26, a first wiring layer 28, and a first contact via 29.

The front insulation layer 22 may be disposed on an upper surface of the gate structure 130 and an upper surface of the upper insulation layer 150 that is disposed on the source and drain patterns 140. The first connection contact portion 24 may include a gate connection contact portion and a drain connection contact portion. The gate connection contact portion may pass through, extend into, or penetrate the front insulation layer 22 and the gate capping layer 138 to be electrically connected to (e.g., in a direct contact with) the gate electrode 132. The drain connection contact portion may pass through, extend into, or penetrate the front insulation layer 22 and the upper insulation layer 150 to be electrically connected to (e.g., in a direct contact with) a drain pattern 140d. In some embodiments, the first connection contact portion 24 may further include a source connection contact portion. The source connection contact portion may pass through, extend into, or penetrate the front insulation layer 22 and the upper insulation layer 150 to be electrically connected to (e.g., in a direct contact with) a source pattern 140s.

In FIG. 1, it is illustrated as an example that the source and drain patterns 140 of the plurality of semiconductor elements 110 are disposed to have an arrangement of a drain pattern 140d, a source pattern 140s, and a drain pattern 140d, and the first connection contact portion 24 includes the gate connection contact portion, the drain connection contact portion, and the source connection contact portion. When the first connection contact portion 24 may include the source connection contact portion, power may be supplied to an upper surface of the source pattern 140s and freedom of a circuit design may be enhanced. However, the embodiments are not limited thereto. The first connection contact portion 24 may include the gate connection contact portion and the drain connection contact portion, and might not include the source connection contact portion. An arrangement of the source and drain patterns 140 of the plurality of semiconductor elements 110 may be variously modified.

The first interlayer insulation layer 26 and the first wiring layer 28 may be disposed on the front insulation layer 22 and the first connection contact portion 24. For example, a plurality of first wiring layers 28 may be spaced apart from each other while interposing the first interlayer insulation layer 26, and may be electrically connected to each other through the first contact via 29 that passes through, extends into, or penetrates the first interlayer insulation layer 26. The first contact via 29 may be formed together with the first wiring layer 28 in a same process, or may be formed in a process different from a process of forming the first wiring layer 28. One first wiring layer 28 of the plurality of first wiring layers 28 that is adjacent to the first connection contact portion 24 may be electrically connected to (e.g., in a direct contact with) the first connection contact portion 24. By the first connection contact portion 24, the first wiring layer 28, and the first contact via 29, the first wiring portion 20 may be connected to have a desirable path to transmit signals to the semiconductor element 110. For example, the first connection contact portion 24, the first wiring layer 28, and the first contact via 29 may form a front signal wiring that transmits signals to the semiconductor element 110.

The first connection contact portion 24, the first wiring layer 28, and/or the first contact via 29 may include or be formed of a conductive material. At least two of the first connection contact portion 24, the plurality of first wiring layers 28, and the first contact via 29 may include a same material or may include different materials. The first connection contact portion 24 and/or the first wiring layer 28 may include a single layer or may include a plurality of layers.

For example, the first connection contact portion 24, the first wiring layer 28, and/or the first contact via 29 may include or be formed of at least one of copper, aluminum, tungsten, molybdenum, titanium, tantalum, nickel, gold, tin, manganese, or cobalt, or include or be formed of an alloy that includes the above material. The front insulation layer 22 or the first interlayer insulation layer 26 may include or be formed of any of various insulating materials to electrically insulate the first wiring layers 28 that are not electrically connected to each other.

The support substrate 40 may be disposed on the first wiring portion 20. In a process of forming the second wiring portion 50, the support substrate 40 may mechanically or structurally support the semiconductor element portion 10 and the first wiring portion 20. The support substrate 40 may be referred to as a sustain substrate, a handling substrate, a carrier substrate, or so on.

In an embodiment, the support substrate 40 may be a semiconductor substrate that includes or is formed of a semiconductor material. For example, the support substrate 40 may be a semiconductor substrate that is formed of a semiconductor material, or a semiconductor substrate that includes a base substrate and a semiconductor layer formed on the base substrate. For example, the support substrate 40 may include or be formed of a single-crystalline or polycrystalline semiconductor (e.g., Si, Ge, or SiGe) substrate, a silicon on insulator (SOI) substrate, or a germanium on insulator (GOI) substrate. For example, the support substrate 40 may be a silicon substrate.

The intermediate layer may be disposed between the first wiring portion 20 and the support substrate 40. For example, the intermediate layer may be the bonding layer 30 that bonds the first wiring portion 20 and the support substrate 40. The intermediate layer may be referred to as an intermediate insert layer, an insert layer, an intervening layer, or so on. The bonding layer 30 will be described later in more detail.

The second wiring portion 50 may be disposed on the second surface 102 of the semiconductor element portion 10. The second wiring portion 50 may be a power wiring portion that is disposed on the second surface 102 of the semiconductor element portion 10 and transmits power to the semiconductor element 110. The second wiring portion 50 may be referred to as a back side power delivery network or a back side power distribution network (BSPDN).

The second wiring portion 50 may include a rear insulation layer 52, a second connection contact portion 54, a second interlayer insulation layer 56, a second wiring layer 58, and a second contact via 59.

The rear insulation layer 52 may be disposed on a lower surface of the active region 120 and the gate structure 130 and lower surfaces of the source and drain patterns 140. The second connection contact portion 54 may include a source connection contact portion. The source connection contact portion may pass through, extend into, or penetrate the rear insulation layer 52 to be electrically connected to (e.g., in a direct contact with) the source pattern 140s.

The second interlayer insulation layer 56 and the second wiring layer 58 may be disposed on the rear insulation layer 52 and the second connection contact portion 54. A plurality of second wiring layers 58 may be spaced apart from each other while interposing the second interlayer insulation layer 56, and may be electrically connected to each other through the second contact via 59 that passes through, extends into, or penetrates the second interlayer insulation layer 56. The second contact via 59 may be formed together with the second wiring layer 58 in a same process, or may be formed in a process different from a process of forming the second wiring layer 58. One second wiring layer 58 of the plurality of second wiring layers 58 that is adjacent to the second connection contact portion 54 may be electrically connected to (e.g., in a direct contact with) the second connection contact portion 54. By the second connection contact portion 54, the second wiring layer 58, and the second contact via 59, the second wiring portion 50 may be connected to have a desirable path to transmit power to the semiconductor element 110. For example, the second connection contact portion 54, the plurality of second wiring layers 58, and the second contact via 59 may form a rear power wiring that transmits the power to the semiconductor element 110.

An outermost wiring layer of the plurality of second wiring layers 58 may include a pad 58p. The pad 58p may be a bonding pad that is disposed at a lower surface of the second wiring portion 50 and is electrically connected to the connection bump 60, an external circuit, or so on.

The second connection contact portion 54, the second wiring layer 58, and/or the second contact via 59 may include or be formed of a conductive material. At least two of the second connection contact portion 54, the plurality of second wiring layers 58, and the second contact via 59 may include a same material or may include different materials. The second connection contact portion 54 and/or the second wiring layer 58 may include a single layer or may include a plurality of layers.

For example, the second connection contact portion 54, the second wiring layer 58, and/or the second contact via 59 may include or be formed of at least one of copper, aluminum, tungsten, molybdenum, titanium, tantalum, nickel, gold, tin, manganese, or cobalt, or include or be formed of an alloy that includes the above material. The rear insulation layer 52 or the second interlayer insulation layer 56 may include or be formed of any of various insulating materials to electrically insulate the second wiring layers 58 that are not be electrically connected to each other.

In FIG. 1, it is illustrated as an example that a thickness of the second wiring layer 58 is greater than a thickness of the first wiring layer 28. When the second wiring layer 58 that transmits the power may have the thickness greater than the thickness of the first wiring layer 28 that transmits the signals, the power may be stably transmitted by the second wiring layer 58. However, the embodiments are not limited thereto, and the thickness of the second wiring layer 58 may be the same as or less than the thickness of the first wiring layer 28.

The semiconductor device 100 may include a wiring or a structure configured to transmit signals from the second wiring portion 50 to the first wiring portion 20. In an embodiment, signals may be supplied to the first wiring portion 20 through a portion of the plurality of second wiring layers 58 and/or a portion of the semiconductor element portion 10.

For example, the second wiring portion 50 may further include a signal wiring that transmits signals other than the rear power wiring. For example, the semiconductor element portion 10 may include a through contact portion (for example, a through silicon via (TSV)) that passes through, extends into, or penetrates the semiconductor element portion 10, and the signal wiring of the second wiring portion 50 and the first wiring portion 20 may be electrically connected to each other through the through contact portion. In some embodiments, the signal wiring of the second wiring portion 50 and the first wiring portion 20 may be electrically connected to each other through a wiring, a circuit, or so on that is included in the semiconductor element portion 10. In some embodiments, the first wiring portion 20 may further include a pad that transmits signals to the semiconductor element portion 10. As described above, a structure that transmits signals to the first wiring portion 20 may be variously modified.

The connection bump 60 may be disposed on the pad 58p of the second wiring layer 58. By the connection bump 60, the semiconductor device 100 may be fixed and electrically connected to a package substrate, a printed circuit board, an interposer, a semiconductor chip, a semiconductor package, or so on.

The connection bump 60 may include or be formed of at least one of copper, aluminum, tungsten, nickel, tin, titanium, tantalum, indium, molybdenum, manganese, cobalt, magnesium, rhenium, beryllium, gallium, or ruthenium, or include or be formed of an alloy that includes the above material. However, the embodiments are not limited thereto.

In FIG. 1, structures of the semiconductor element portion 10, the first wiring portion 20, the second wiring portion 50, and the connection bump 60 are schematically illustrated as an example, but the embodiments are not limited thereto. Accordingly, a structure, an arrangement, or so on of a member related to a power transmission and a member related to a signal transmission may be variously modified according to a type, a kind, a design, or so on of the semiconductor device 100.

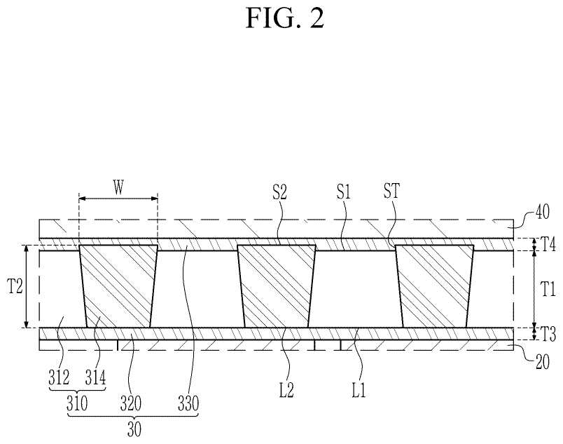

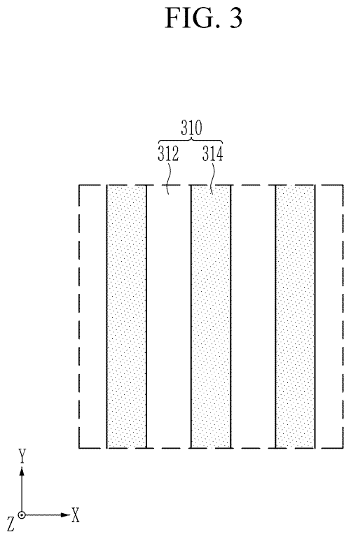

Referring to FIG. 2 and FIG. 3 together with FIG. 1, the intermediate layer (e.g., the bonding layer 30) that is included in the semiconductor device 100 according to an embodiment will be described in more detail.

FIG. 2 is an enlarged cross-sectional view of a portion A in FIG. 1. FIG. 3 is a plan view that illustrates a partial portion of the pattern layer 310 of the bonding layer 30 included in the semiconductor device 100 illustrated in FIG. 1.

Referring to FIG. 1 to FIG. 3, the intermediate layer (e.g., the bonding layer 30) according to an embodiment may include a pattern layer 310. The pattern layer 310 may include a first pattern 312 and a second pattern 314. The bonding layer 30 may include a first insulation layer 320 disposed between the first wiring portion 20 and the pattern layer 310, and further include a second insulation layer 330 disposed between the pattern layer 310 and the support substrate 40.

In an embodiment, the pattern layer 310 may include the first pattern 312 and the second pattern 314. The first pattern 312 may include or be formed of an insulating material. The second pattern 314 may have thermal conductivity greater than thermal conductivity of the first pattern 312, and may be electrically insulated from the first wiring portion 20. The second pattern 314 may include or be formed of a conductive material (e.g., metal or a metal alloy). The first pattern 312 may be an insulation pattern that includes or is formed of an insulating material. The second pattern 314 may be a heat dissipation pattern that provides a heat dissipation path. The second pattern 314 may be a pattern that is not connected to the first wiring portion 20 and/or to the second wiring portion 50 and does not contribute to an electrical connection. The second pattern 314 may be referred to as a heat dissipation pattern, a conductive pattern, a metal pattern, a floating pattern, a floating conductive pattern, a floating metal pattern, a dummy pattern, a dummy conductive pattern, a dummy metal pattern, or so on.

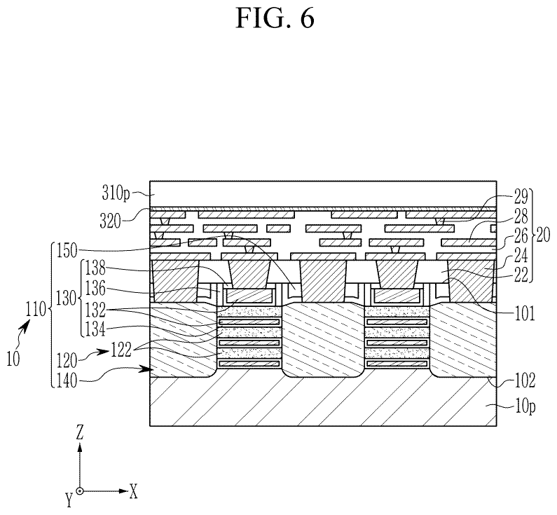

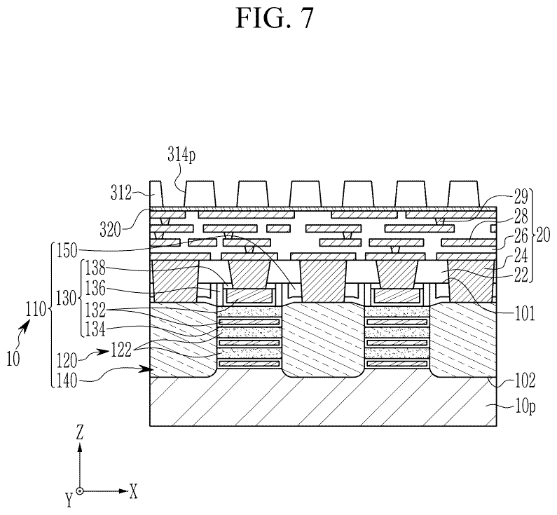

In an embodiment, the pattern layer 310 may be formed by forming the preliminary insulation layer 310p (refer to FIG. 6) that includes or is formed of an insulating material, forming an opening 314p (refer to FIG. 7) through removing a portion of the preliminary insulation layer 310p, and filling or providing a conductive material in the opening 314p. A remained portion of the preliminary insulation layer 310p may form the first pattern 312, and a portion where the conductive material is at least partially filled in the opening 314p may form the second pattern 314. As described above, the pattern layer 310 that includes the first pattern 312 and the second pattern 314 may be formed through a simple manufacturing process. A manufacturing method of the pattern layer 310 will be described later in more detail in a manufacturing method of the semiconductor device 100.

In a cross-sectional view, a side surface of the second pattern 314 may have an inclined surface so that a width of the second pattern 314 decreases toward the first wiring portion 20. This may be because an etching process may be performed at a surface of the preliminary insulation layer 310p opposite to the first wiring portion 20 in a process of forming the opening 314p. However, the embodiments are not limited thereto, and the side surface of the second pattern 314 may be a vertical surface and the second pattern 314 may have a substantially uniform width. Various other modifications are possible.

The first pattern 312 may include or be formed of oxide, nitride, oxynitride, or so on. For example, the first pattern 312 may include or be formed of silicon oxide (SiOx), silicon nitride (SiNx), silicon oxynitride (SiONx), or so on.

The second pattern 314 that includes a conductive material may include or be formed of metal or a metal alloy. For example, the second pattern 314 may include or be formed of at least one of copper, aluminum, tungsten, molybdenum, titanium, tantalum, nickel, gold, tin, manganese, or cobalt, or may include or be formed of an alloy that includes the above material. When the second pattern 314 includes the conductive material (e.g., the metal or the metal alloy), the second pattern 314 may have relatively high thermal conductivity.

As described above, in an embodiment, the pattern layer 310 may include the first pattern 312 and the second pattern 314 that are disposed on a same plane or a same level and include different materials (e.g., the first pattern 312 and the second pattern 314 are coplanar).

As described herein, the first pattern 312 and the second pattern 314 being disposed on a same plane or a same level may refer to at least a portion of the first pattern 312 and at least a portion of the second pattern 314 may be disposed on a same position in the thickness direction of the semiconductor device 100 (the Z-axis direction in the drawings) (e.g., the first pattern 312 and the second pattern 314 at least partially overlap each other in the X-axis direction). In some embodiments, the phrase that the first pattern 312 and the second pattern 314 are disposed on a same plane or a same level may refer to at least a portion of a side surface of the second pattern 314 is adjacent to (e.g., is in contact with) at least a portion of a side surface of the first pattern 312, or a first surface L1 of the first pattern 312 and a first surface L2 of the second pattern 314 may form a same plane or a continuous surface, or a second surface S1 of the first pattern 312 and a second surface S2 of the second pattern 314 may form a same plane or a continuous surface.

In the specification, the first surface L1 of the first pattern 312 or the first surface L2 of the second pattern 314 may be a surface that is adjacent to the first wiring portion 20 (e.g., a surface that is adjacent to the first insulation layer 320). The second surface S1 of the second pattern 314 or the second surface S2 of the second pattern 314 may be opposite to the first surface L1 of the first pattern 312 or the first surface L2 of the second pattern 314, and may be a surface that is adjacent to the support substrate 40 (e.g., a surface of that is adjacent to the second insulation layer 330).

The first insulation layer 320 may be disposed between the first wiring portion 20 and the pattern layer 310, and the second insulation layer 330 may be disposed between the pattern layer 310 and the support substrate 40.

The first insulation layer 320 may be disposed at least between the second pattern 314 of the pattern layer 310 and the first wiring portion 20 and may separate the second pattern 314 of the pattern layer 310 and the first wiring portion 20 to have an interval and/or electrically insulate the second pattern 314 of the pattern layer 310 and the first wiring portion 20. The first insulation layer 320 may act as an etching stopping layer in a process of forming the opening 314p (refer to FIG. 7) in the preliminary insulation layer 310p (refer to FIG. 6). Therefore, the first insulation layer 320 may be referred to as an electrical insulation layer, an etching stopping layer, or so on.

In an embodiment, the first insulation layer 320 may include a portion disposed between the first pattern 312 and the first wiring portion 20 and a portion disposed between the second pattern 314 and the first wiring portion 20, and may be entirely disposed between the pattern layer 310 and the first wiring portion 20.

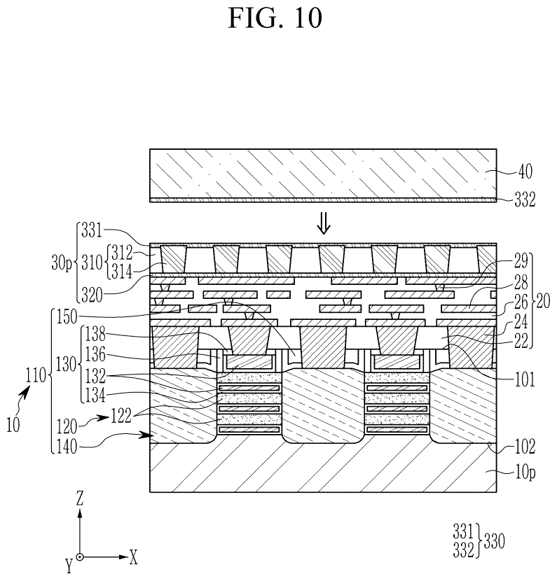

The second insulation layer 330 may be disposed at least between the first pattern 312 of the pattern layer 310 and the support substrate 40 and physically and structurally bond the first wiring portion 20 and the support substrate 40 (e.g., the pattern layer 310 and the support substrate 40). Therefore, the second insulation layer 330 may be referred to as a bonding insulation layer. The second insulation layer 330 may be formed by an insulation-layer bonding where a first insulation bonding portion 331 (refer to FIG. 10) on the pattern layer 310 and a second insulation bonding portion 332 (refer to FIG. 10) on the support substrate 40 are bonded to each other. This will be described later in more detail in a manufacturing method of the semiconductor device 100.

In an embodiment, the second insulation layer 330 may include a portion disposed between the first pattern 312 and the support substrate 40 and a portion disposed between the second pattern 314 and the support substrate 40, and may be entirely disposed between the pattern layer 310 and the support substrate 40.

The first insulation layer 320 may include an insulating material different from an insulating material of the first pattern 312, and/or the second insulation layer 330 may include an insulating material different from an insulating material of the first pattern 312. For example, the first insulation layer 320 may include an insulating material different from an insulating material of the first pattern 312 and may stably act as an etching stopping layer, and the second insulation layer 330 may include an insulating material different from an insulating material of the first pattern 312 and may stably act as a bonding insulation layer. However, the embodiments are not limited thereto, and the first insulation layer 320 and/or the second insulation layer 330 may include a same insulating material as the first pattern 312.

For example, the first insulation layer 320 and the second insulation layer 330 may include a same material. Thereby, the first insulation layer 320 and the second insulation layer 330 may be formed through using a same or similar manufacturing process, thereby simplifying a manufacturing process.

In some embodiments, the first insulation layer 320 and the second insulation layer 330 may include different materials. For example, the first insulation layer 320 may include an insulating material having a dielectric constant less than a dielectric constant of the second insulation layer 330, and properties of the first insulation layer 320 acting as the electrical insulation layer may be enhanced. For example, the second insulation layer 330 may include an insulating material having a better bonding property than the second insulation layer 330, and properties of the second insulation layer 330 acting as the bonding insulation layer may be enhanced.

However, the embodiments are not limited thereto. In some embodiments, the second insulation layer 330 may have a dielectric constant less than a dielectric constant of the first insulation layer 320, and/or the first insulation layer 320 may have a better bonding property than the second insulation layer 330.

In an embodiment, the first insulation layer 320 and/or the second insulation layer 330 may include or be formed of a material of oxide, nitride, or carbide. For example, the first insulation layer 320 and/or the second insulation layer 330 may include or be formed of at least one of silicon oxide (SiOx), silicon nitride (SiNx), silicon carbonitride (SiCNx), silicon oxycarbide (SiOCx), silicon oxynitride (SiONx), silicon oxycarbonitride (SiOCNx), or aluminum nitride (AlNx). In an embodiment, the first insulation layer 320 and the second insulation layer 330 may include a same material, for example, silicon carbonitride (SiCNx). For example, the first insulation layer 320 may include a material having a dielectric constant less than a dielectric constant of the first pattern 312, and properties of the first insulation layer 320 acting as the electrical insulation layer may be enhanced. However, the embodiments are not limited to a material of the first insulation layer 320 and/or the second insulation layer 330.

In an embodiment, the second pattern 314 that is included in the pattern layer 310 of the bonding layer 30 may have high thermal conductivity, thereby improving effective thermal conductivity of the bonding layer 30 and forming a heat dissipation path through the second pattern 314.

The bonding layer 30 may be an intermediate layer that is disposed between the first wiring portion 20 and the support substrate 40. If the thermal conductivity of the bonding layer 30 is low, a heat flow through the bonding layer 30 may be deteriorated or inhibited. In an embodiment, even though the second pattern 314 may be spaced apart from the first wiring portion 20 and/or the support substrate 40 by the first insulation layer 320 and/or the second insulation layer 330, heat may be easily dissipated by a heat conduction that passes through or extends into the second pattern 314 via the first insulation layer 320 and/or the second insulation layer 330 of a small thickness. That is, the second pattern 314 disposed between the first insulation layer 320 and the second insulation layer 330 may form a heat dissipation path where heat is dissipated in a direction toward the support substrate 40.

More particularly, the semiconductor element portion 10 and/or the first wiring portion 20 may generate a relatively large amount of heat during an operation of the semiconductor device 100. When the heat generated at the semiconductor element portion 10 and/or the first wiring portion 20 may be dissipated to the support substrate 40 through the first wiring portion 20 and the bonding layer 30, the second pattern 314 may form the heat dissipation path. The support substrate 40 may have a relatively large thickness. Accordingly, when the heat dissipation path toward the support substrate 40 may be provided, the heat may be effectively dissipated through the support substrate 40. For reference, the first wiring layer 28 of the first wiring portion 20 may have a thickness that is less than the thickness of the second wiring layer 58 of the second wiring portion 50, and a relatively large amount of heat may be generated at the first wiring portion 20, but the embodiments are not limited thereto.

As in the above, in an embodiment, the heat dissipation path in the direction toward the support substrate 40 may be provided and an enhanced heat dissipation property may be achieved, compared to a comparative example where heat is dissipated only along a path toward a second wiring portion and/or a connection bump. Further, the bonding layer 30 may be formed by a relatively simpler manufacturing process.

In an embodiment, the second pattern 314 may be electrically insulated from the first wiring portion 20, the semiconductor element portion 10, and/or the second wiring portion 50 by the first insulation layer 320. Accordingly, the second pattern 314 may have any of various structures, and a structure of the first wiring portion 20, the semiconductor element portion 10, and/or the second wiring portion 50 may be simplified and design freedom may be enhanced. That is, a heat dissipation property may be enhanced without increasing a wiring path and electrical resistance of the first wiring portion 20, the semiconductor element portion 10, and/or the second wiring portion 50.

On the other hand, in a comparative example where a heat dissipation pattern is electrically connected to a first wiring portion, a semiconductor element portion, a second wiring portion, and/or a connection bump, the first wiring portion, the semiconductor element portion, and/or the second wiring portion may include an addition wiring or structure connected to the heat dissipation pattern and a number of connection bumps may increase. Accordingly, a structure or an arrangement of the first wiring portion, the semiconductor element portion, a second wiring portion, and/or the connection bump may be complicated or design freedom may be deteriorated or reduced. That is, a wiring path, electrical resistance of a wiring, or so on may increase.

In an embodiment, the second pattern 314 that includes the conductive material may be partially formed in a plan view, and cost of a process of forming the pattern layer 310 may be reduced. The first pattern 312 that includes the insulating material and has a stable connection property with the first insulation layer 320 and/or the second insulation layer 330 may be disposed at a periphery (e.g., edge, side, or end) of the second pattern 314. The pattern layer 310 that includes the second pattern 314 may have a stable connection property with the first insulation layer 320 and/or the second insulation layer 330. Thereby, a structural stability of the bonding layer 30 may be enhanced.

In an embodiment, the pattern layer 310 may be disposed between the first insulation layer 320 and the second insulation layer 330 to have a sandwich structure. The pattern layer 310 may be spaced apart and/or electrically insulated from the first wiring portion 20 by the first insulation layer 320, and may be spaced apart and/or electrically insulated from the support substrate 40 and may be stably bonded to the support substrate 40 by the second insulation layer 330.

In an embodiment, a thickness of the pattern layer 310 may be greater than a thickness T3 of the first insulation layer 320, and/or may be greater than a thickness T4 of the second insulation layer 330. More particularly, a thickness T1 of the first pattern 312 may be greater than the thickness T3 of the first insulation layer 320, and/or may be greater than the thickness T4 of the second insulation layer 330. A thickness T2 of the second pattern 314 may be greater than the thickness T3 of the first insulation layer 320, and/or or may be greater than the thickness T4 of the second insulation layer 330. The thickness T1 of the first pattern 312, the thickness T2 of the second pattern 314, the thickness T3 of the first insulation layer 320, or the thickness T4 of the second insulation layer 330 may refer to a thickness in the thickness direction of the semiconductor device 100 (the Z-axis direction in the drawings), for example, a maximum thickness.

Therefore, the pattern layer 310 that includes the first pattern 312 and the second pattern 314 may be stably formed. However, the embodiments are not limited thereto. The thickness T1 of the first pattern 312 may be substantially the same as or less than the thickness T3 of the first insulation layer 320, and/or may be substantially the same as or less than the thickness T4 of the second insulation layer 330. The thickness T2 of the second pattern 314 may be substantially the same as or less than the thickness T3 of the first insulation layer 320, and/or may be substantially the same as or less than the thickness T4 of the second insulation layer 330.

In a plan view, an area of the first pattern 312 may be greater than an area of the second pattern 314. For example, in a plan view, a ratio of the area of the second pattern 314 to an entire area of the first pattern 312 and the second pattern 314 may be 10% or more (e.g., 20% or more, as an example, 30% or more), and less than 50%. The second pattern 314 may have a relatively small area as described above, and thus, the time and cost of a process forming the second pattern 314 may be reduced. However, the embodiments are not limited thereto. In a plan view, the area of the first pattern 312 may be the same as or less than the area of the second pattern 314.

The thickness T3 of the first insulation layer 320 may be the same as or greater than the thickness T4 of the second insulation layer 330. When the thickness T3 of the first insulation layer 320 is same as the thickness T4 of the second insulation layer 330, the first insulation layer 320 and the second insulation layer 330 may be formed by a same process condition, thereby simplifying a manufacturing process. When the thickness T3 of the first insulation layer 320 is greater than the thickness T4 of the second insulation layer 330, the pattern layer 310 that includes the second pattern 314 and the first wiring portion 20 may be stably electrically insulated from each other. However, the embodiments are not limited thereto, and the thickness T3 of the first insulation layer 320 may be less than the thickness T4 of the second insulation layer 330.

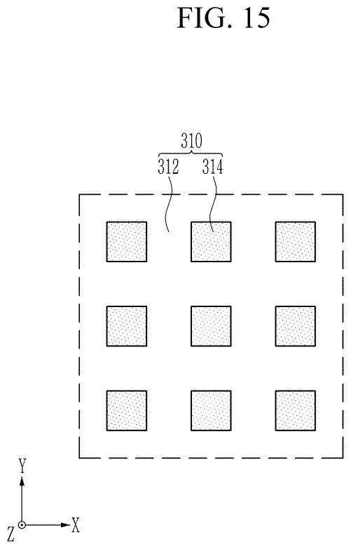

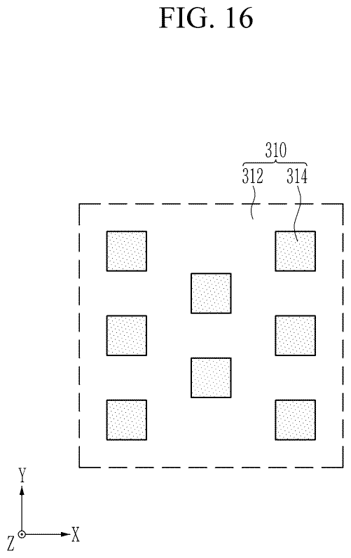

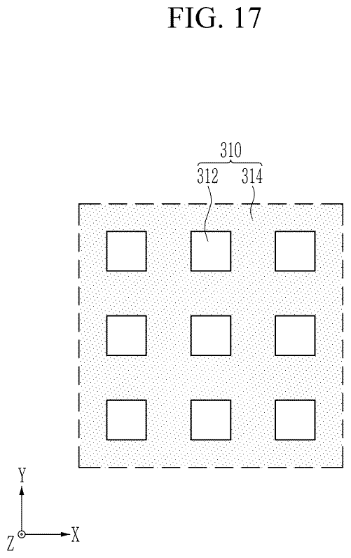

In the thickness direction of the semiconductor device 100 (the Z-axis direction in the drawings), a ratio (W/T2) of a width W of the second pattern 314 to the thickness T2 of the second pattern 314 may be 0.5 or more. The width W of the second pattern 314 may be a line width perpendicular to an extension direction of the second pattern 314 in a plan view. For example, when the second pattern 314 has a linear shape (e.g., a line shape or a stripe shape as illustrated in FIG. 3), the width W of the second pattern 314 may refer to a line width of the linear shape, for example, a maximum width. For example, when the second pattern 314 has an enclosed shape (e.g., an island shape as illustrated in FIG. 15 or FIG. 16), the width W of the second pattern 314 may refer to a long width. In some embodiments, when the second pattern 314 has an enclosed shape (e.g., a mesh shape as illustrated in FIG. 17), the width W of the second pattern 314 may refer to a line width of an extended portion, for example, a maximum width.

When the ratio (W/T2) of the width W of the second pattern 314 to the thickness T2 of the second pattern 314 may be 0.5 or more, the second pattern 314 may have the relatively small thickness T2, and a total length of the heat dissipation path may be reduced and the area of the second pattern 314 may be secured to a certain level or more. Accordingly, the heat dissipation property may be enhanced. For example, the ratio (W/T2) of the width W of the second pattern 314 to the thickness T2 of the second pattern 314 may be 1 or more. That is, the width W of the second pattern 314 may be the same as or greater than the thickness T2 of the second pattern 314. However, the embodiments are not limited thereto. In some embodiments, the width W of the second pattern 314 may be less than the thickness T2 of the second pattern 314, or the ratio (W/T2) of the width W of the second pattern 314 to the thickness T2 of the second pattern 314 may be less than 0.5.

In an embodiment, at least a partial portion of the second surface S2 of the second pattern 314 may include a portion protruding or extending from the second surface S1 of the first pattern 312 toward the support substrate 40 (e.g., the second insulation layer 330). Therefore, a thickness (e.g., an average thickness) of a portion of the second insulation layer 330 disposed between the second pattern 314 and the support substrate 40 may be less than a thickness (e.g., an average thickness) of a portion of the second insulation layer 330 disposed between the first pattern 312 and the support substrate 40. Accordingly, a distance between the second pattern 314 and the support substrate 40 may be reduced, and an area of the second pattern 314 and the support substrate 40 facing each other may increase. Thereby, the heat dissipation property by the second pattern 314 may be enhanced.

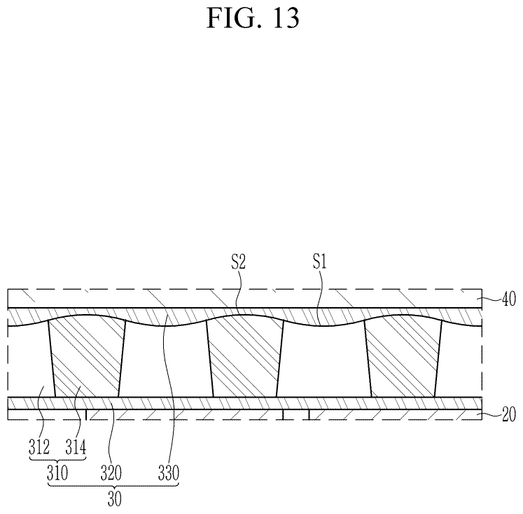

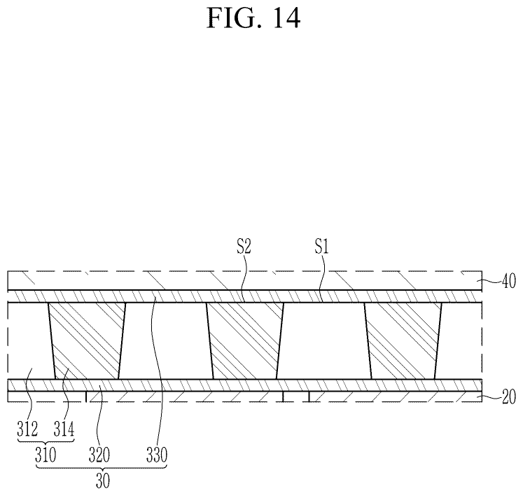

In FIG. 1 and FIG. 2, it is illustrated as an example that each of the second surface S1 of the first pattern 312 and the second surface S2 of the second pattern 314 has a flat surface, and a step ST is disposed between the second surface S1 of the first pattern 312 and the second surface S2 of the second pattern 314. Further, it is illustrated as an example that the first surface L1 of the first pattern 312 and the first surface L2 of the second pattern 314 have flat surfaces, and the first surface L1 of the first pattern 312 and the first surface L2 of the second pattern 314 may be disposed on a same plane without a step. However, the embodiments are not limited thereto, and a shape, an arrangement, or so on of the second surface S1 of the first pattern 312, the second surface S2 of the second pattern 314, the first surface L1 of the first pattern 312, or the first surface L2 of the second pattern 314 may be variously modified. Additional embodiments of the second surface S1 of the first pattern 312 and the second surface S2 of the second pattern 314 will be described later with reference to FIG. 13 and FIG. 14.

In an embodiment, the second pattern 314 may have any of various planar shapes. For example, the second pattern 314 may have a line shape or a stripe shape that includes portions of line shapes as illustrated in FIG. 3. Therefore, the second pattern 314 may be stably formed to have an area of a certain level or more. In FIG. 3, it is illustrated as an example that an entire portion of the second pattern 314 extends in one direction and has a uniform line width. However, the embodiments are not limited thereto, and the second pattern 314 may include a width change portion which width is changed, or may include portions extending in different directions. In FIG. 3, it is illustrated as an example that widths of the plurality of second patterns 314 are the same, but a plurality of second patterns 314 having different widths may be included. Various other modifications are possible.

According to an embodiment, the intermediate layer disposed between the first wiring portion 20 and the support substrate 40 (e.g., the bonding layer 30 configured to bond the first wiring portion 20 and the support substrate 40) may include the heat dissipation pattern (e.g., the second pattern 314), and an effective thermal conductivity of the intermediate layer (e.g., the bonding layer 30) may be improved and the heat dissipation path toward the support substrate 40 may be formed. Accordingly, the heat dissipation property of the semiconductor device 100 may be enhanced by a simple structure. Since the heat dissipation pattern (e.g., the second pattern 314) may be electrically insulated from the first wiring portion 20, the heat dissipation property may be enhanced without increasing a wiring path and electrical resistance of the first wiring portion 20. Therefore, performance and reliability of the semiconductor device 100 may be enhanced.

The first pattern 312 may be further included at the periphery of the second pattern 314, and the cost of the process of forming the intermediate layer (e.g., the bonding layer 30) that includes the second pattern 314 may be reduced and the structural stability of the intermediate layer (e.g., the bonding layer 30) may be enhanced. Since the pattern layer 310 that includes the first pattern 312 and the second pattern 314 is disposed between the first insulation layer 320 and the second insulation layer 330 in the intermediate layer (e.g., the bonding layer 30), the pattern layer 310 may be stably bonded to the support substrate 40 in a state the pattern layer 310 is spaced apart and/or electrically insulated from the first wiring portion 20 and the support substrate 40.

Referring to FIG. 4 to FIG. 12, a manufacturing method of a semiconductor device 100 according to an embodiment will be described in detail.

FIG. 4 to FIG. 12 are cross-sectional views that illustrate a manufacturing method of a semiconductor device 100 according to an embodiment.

As illustrated in FIG. 4, a semiconductor element portion 10 may be formed on a semiconductor substrate 10p.

The semiconductor substrate 10p may be a semiconductor substrate that includes or is formed of a semiconductor material. For example, the semiconductor substrate 10p may be a semiconductor substrate that is formed of a semiconductor material, or a semiconductor substrate that includes a base substrate and a semiconductor layer formed on the base substrate. For example, the semiconductor substrate 10p may include or be formed of a single-crystalline or polycrystalline semiconductor (e.g., Si, Ge, or SiGe) substrate, a silicon on insulator substrate, or a germanium on insulator substrate. For example, the semiconductor substrate 10p may be a silicon substrate.

A process of forming a transistor (i.e., a semiconductor element 110 that is included in the semiconductor element portion 10) will be simply described.

First, a stacking structure where a plurality of channel layers 122 and a plurality of sacrificial layers are alternately stacked may be formed on the semiconductor substrate 10p. For example, the plurality of channel layers 122 and the plurality of sacrificial layers may be formed by an epitaxial growth process. The sacrificial layers may be removed in a subsequent process to provide a space where a gate insulation layer 134 and a gate electrode 132 are disposed. The sacrificial layer may include or be formed of a material having an etching selectivity with respect to the channel layer 122 for an etching material that etches the channel layer 122. For example, the channel layer 122 may include or be formed of Si, and the sacrificial layer may include or be formed of SiGe.

A dummy gate may be formed on an active region 120. The dummy gate may be replaced with the gate insulation layer 134 and the gate electrode 132 in a subsequent process. For example, dummy gate may include or be formed of polycrystalline silicon (Si) or so on. In some embodiments, gate spacers 136 may be further formed at both sides of the dummy gate.

By an etching process using the dummy gate and/or the gate spacer 136 as a mask, the active region 120 may be etched. In portions where the active region 120 is etched, source and drain patterns 140 may be formed from the semiconductor substrate 10p and/or the upper surface of the channel layer 122 by using a selective epitaxial growth process. An upper insulation layer 150 may be formed before and/or after a process of forming the source and drain patterns 140. That is, a process order of the source and drain patterns 140 and the upper insulation layer 150 may be variously modified.

The dummy gate and the sacrificial layer may be sequentially removed, and then, the gate insulation layer 134 and the gate electrode 132 may be formed in a space where the dummy gate and the sacrificial layer are removed. The gate insulation layer 134 may be conformally formed on the space where the dummy gate and the sacrificial layer are removed, and the gate electrode 132 may fill the space on the gate insulation layer 134. A gate capping layer 138 may be formed on the gate insulation layer 134 and/or the gate electrode 132 that is disposed on the active region 120.

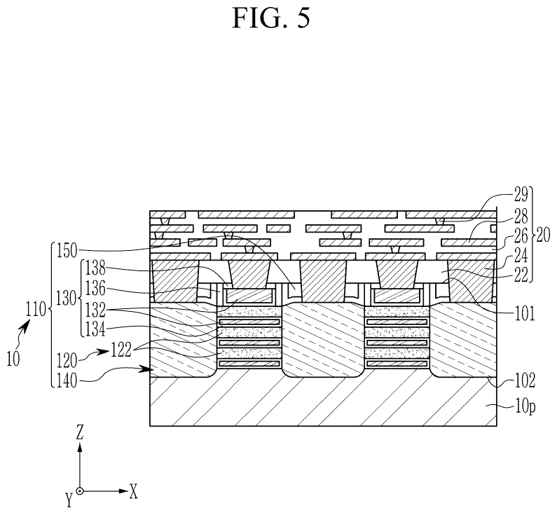

Subsequently, as illustrated in FIG. 5, a first wiring portion 20 may be formed on a first surface 101 of the semiconductor element portion 10. More particularly, a front insulation layer 22 may be formed, first connection contact portions 24 that are electrically connected to the gate electrode 132 and at least a part of the source and drain patterns 140 may be formed, and a first interlayer insulation layer 26, a first wiring layer 28, and a first contact via 29 may be formed. For the process of forming the front insulation layer 22 or the first interlayer insulation layer 26, any of various processes (e.g., a deposition process or so on) may be performed. For the process of forming the first connection contact portion 24, the first wiring layer 28, or the first contact via 29, any of various processes (e.g., a deposition process, a plating process, or so on) may be performed.

Subsequently, as illustrated in FIG. 6 to FIG. 9, a preliminary bonding layer 30p may be formed on the first wiring portion 20.

More particularly, as illustrated in FIG. 6, a first insulation layer 320 and a preliminary insulation layer 310p may be formed on the first wiring portion 20. For the process of forming the first insulation layer 320 or the preliminary insulation layer 310p, any of various processes (e.g., a deposition process or so on) may be performed.

Subsequently, as illustrated in FIG. 7, a partial portion of the preliminary insulation layer 310p (refer to FIG. 6) may be removed to form an opening 314p. A portion of the preliminary insulation layer 310p other than the opening 314p may form a first pattern 312.

For example, a mask that has an opening portion corresponding to the opening 314p may be formed on the preliminary insulation layer 310p, and a portion of the preliminary insulation layer 310p corresponding to the opening 314p may be removed through the opening portion. Therefore, the opening 314p may be formed. After forming the opening 314p, the mask may be removed.

For example, the mask that has the opening portion may be formed by a photolithography process, and the process of removing the portion of the preliminary insulation layer 310p may be performed by using an etching process (e.g., a dry etching process or so on). However, the embodiments are not limited thereto, and the mask may be formed by any of various processes, the process of removing the portion of the preliminary insulation layer 310p may be performed by any of various processes, or the process of removing the mask may be performed by any of various processes.

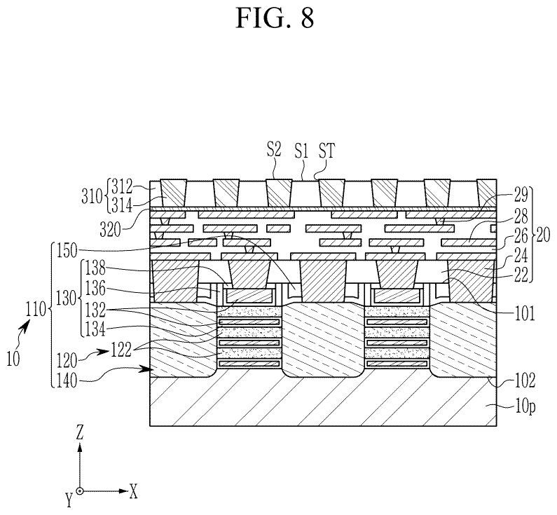

Subsequently, as illustrated in FIG. 8, a conductive material (e.g., metal or a metallic material) may be at least partially filled in the opening 314p to form a second pattern 314. Thereby, a pattern layer 310 that includes the first pattern 312 and the second pattern 314 may be formed. For the process of at least partially filling the conductive material in the opening 314p, any of various processes (e.g., a deposition process, a plating process, or so on) may be performed. After the process of filling the conductive material in the opening 314p, a chemical mechanical polishing (CMP) process may be performed.

For example, by a difference in hardness of the first pattern 312 and the second pattern 314, a step ST may be disposed at a boundary between a second surface S1 of the first pattern 312 and a second surface S2 of the second pattern 314 after the chemical mechanical polishing process. In some embodiments, a material that etches the first pattern 312 more than the second pattern 314 may be used in the chemical mechanical polishing process so that the step ST may be disposed at the boundary between the second surface S1 of the first pattern 312 and the second surface S2 of the second pattern 314. In some embodiments, by adjusting a process condition of the chemical mechanical polishing process, the step ST may be disposed at the boundary between the second surface S1 of the first pattern 312 and the second surface S2 of the second pattern 314. By various methods other than the above, the step ST may be disposed at the boundary between the second surface S1 of the first pattern 312 and the second surface S2 of the second pattern 314. However, the embodiments are not limited thereto, and the second surface S1 of the first pattern 312 and the second surface S2 of the second pattern 314 may have a structure other than the above structure after the chemical mechanical polishing process. This will be described later in detail with reference to FIG. 13 and FIG. 14.

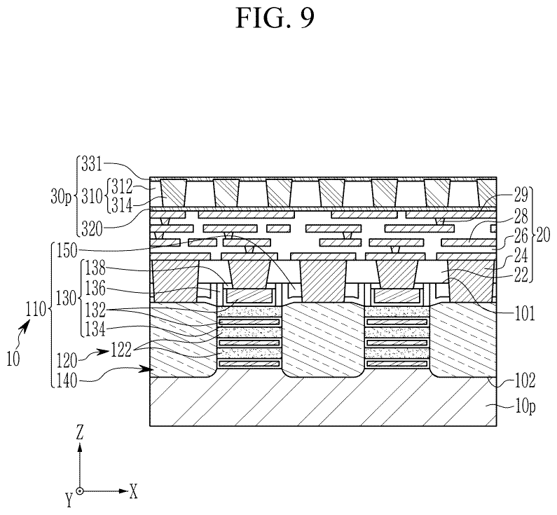

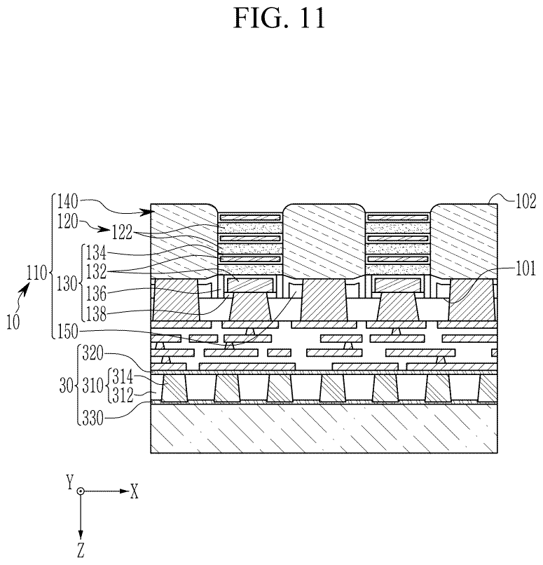

Subsequently, as illustrated in FIG. 9, a preliminary bonding layer 30p may be formed by forming a first insulation bonding portion 331 of a second insulation layer 330 (refer to FIG. 11) on the pattern layer 310. The first insulation bonding portion 331 may be a portion of the second insulation layer 330. For the process of forming the first insulation bonding portion 331, any of various processes (e.g., a deposition process or so on) may be used.

Subsequently, as illustrated in FIG. 10, a second insulation bonding portion 332 of the second insulation layer 330 (refer to FIG. 11) that is disposed on a support substrate 40 and the first insulation bonding portion 331 of the second insulation layer 330 that is disposed on the pattern layer 310 may be bonded to each other. Accordingly, by the second insulation layer 330 that includes the first insulation bonding portion 331 and the second insulation bonding portion 332, the pattern layer 310 and the support substrate 40 may be bonded.

For the process of forming the second insulation bonding portion 332 on the support substrate 40, any of various processes (e.g., a deposition process or so on) may be performed. For the process of bonding the pattern layer 310 and the support substrate 40 using the first insulation bonding portion 331 and the second insulation bonding portion 332, any of various processes, such as, a bonding process using heat and pressure or so on, may be performed.

Subsequently, as illustrated in FIG. 11, in a thickness direction of a semiconductor device (a Z-axis direction in the drawings), at least a partial portion of the semiconductor substrate 10p (refer to FIG. 10) may be removed. For example, for the process of removing at least the partial portion of the semiconductor substrate 10p, any of various processes (an etching process, a chemical mechanical polishing process, or so on) may be used.

In FIG. 11, it is illustrated as an example that the semiconductor substrate 10p is entirely removed and the semiconductor substrate 10p does not remain. However, the embodiments are not limited thereto. In an embodiment, a portion of the semiconductor substrate 10p that is adjacent to the active region 120 and/or the gate structure 130 might not be removed to form a lower pattern.

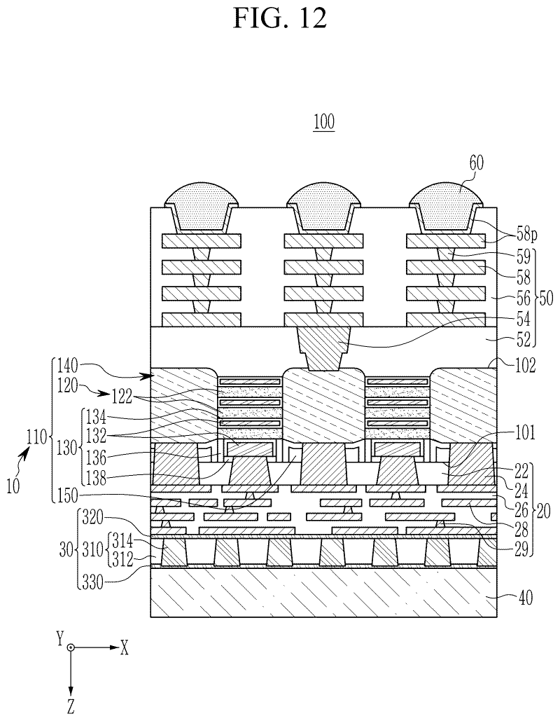

Subsequently, as illustrated in FIG. 12, a second wiring portion 50 may be formed on a second surface 102 of the semiconductor element portion 10. More particularly, a rear insulation layer 52 may be formed, a second connection contact portion 54 that is electrically connected to at least one of the source and drain patterns 140 (e.g., a source pattern) may be formed, and a second interlayer insulation layer 56, a second wiring layer 58, and a second contact via 59 may be formed. For the process of forming the rear insulation layer 52 or the second interlayer insulation layer 56, any of various processes (e.g., a deposition process or so on) may be performed. For the process of forming the second connection contact portion 54, the second wiring layer 58, or the second contact via 59, any of various processes (e.g., a deposition process, a plating process, or so on) may be performed. A connection bump 60 may be formed on a pad 58p of the second wiring portion 50. For the process of forming the connection bump 60, any of various processes may be performed.

According to an embodiment, by a process where the opening 314p is formed by patterning of the preliminary insulation layer 310p and the conductive material is at least partially filled in the opening 314p, the pattern layer 310 that includes the first pattern 312 and the second pattern 314 may be formed. Accordingly, a semiconductor device 100 having an enhanced performance and reliability may be formed by a simple manufacturing process.

Hereinafter, referring to FIG. 13 to FIG. 19, semiconductor devices according to additional embodiments will be described in more detail. To the extent that an element is not described in detail below, it may be understood that the element is at least similar to a corresponding element that has been described elsewhere within the present disclosure. A portion which is not described in the above will be described in detail.

FIG. 13 is a cross-sectional view that illustrates a partial portion of a semiconductor device according to another embodiment. FIG. 13 illustrates a portion corresponding to FIG. 2.

Referring to FIG. 13, in a pattern layer 310 of a bonding layer 30 according to embodiment, at least a portion of a second surface S2 of a second pattern 314 may include a portion protruding or extending from a second surface S1 of a first pattern 312 toward a support substrate 40 (e.g., a second insulation layer 330). The second surface S1 of the first pattern 312 and the second surface S2 of the second pattern 314 may be surfaces that are adjacent to the support substrate 40 (e.g., surfaces that are adjacent to the second insulation layer 330). For example, the second surface S2 of the second pattern 314 may have a convex shape toward the support substrate 40 (e.g., the second insulation layer 330), and the second surface S1 of the first pattern 312 may have a concave shape.

In an embodiment, a thickness (e.g., an average thickness) of a portion of the second insulation layer 330 disposed between the second pattern 314 and the support substrate 40 may be less than a thickness (e.g., an average thickness) of a portion of the second insulation layer 330 disposed between the first pattern 312 and the support substrate 40. Therefore, a heat dissipation property by the second pattern 314 may be enhanced. Since a step might not be disposed between the second surface S1 of the first pattern 312 and the second surface S2 of the second pattern 314, a structural stability may be further enhanced.

By a chemical mechanical polishing process (refer to FIG. 8) performed for forming the first pattern 312 and the second pattern 314, the second surface S1 of the first pattern 312 may have the concave shape and the second surface S2 of the second pattern 314 may have the convex shape as in the above.

For example, due to a difference in hardness of the first pattern 312 and the second pattern 314, the second surface S1 of the first pattern 312 may have the concave shape and the second surface S2 of the second pattern 314 may have the convex shape after the chemical mechanical polishing process. In some embodiments, a material that etches the first pattern 312 more than the second pattern 314 may be used in the chemical mechanical polishing process so that the second surface S1 of the first pattern 312 may have the concave shape and the second surface S2 of the second pattern 314 may have the convex shape after the chemical mechanical polishing process. In some embodiments, by adjusting a process condition of the chemical mechanical polishing process, the second surface S1 of the first pattern 312 may have the concave shape and the second surface S2 of the second pattern 314 may have the convex shape after the chemical mechanical polishing process. By various methods other than those described above, the second surface S1 of the first pattern 312 may have the concave shape and the second surface S2 of the second pattern 314 may have the convex shape.

FIG. 14 is a cross-sectional view that illustrates a partial portion of a semiconductor device according to another embodiment. FIG. 14 illustrates a portion corresponding to FIG. 2.

Referring to FIG. 14, in a pattern layer 310 of a bonding layer 30 according to embodiment, a second surface S1 of a first pattern 312 that is adjacent to a second insulation layer 330 may be disposed on a same plane as a second surface S2 of a second pattern 314 that is adjacent to the second insulation layer 330. Accordingly, a thickness (e.g., an average thickness) of a portion of the second insulation layer 330 disposed between the second pattern 314 and the support substrate 40 may be substantially same as a thickness (e.g., an average thickness) of a portion of the second insulation layer 330 disposed between the first pattern 312 and the support substrate 40.

FIG. 15 is a plan view that illustrates a portion of a pattern layer of a bonding layer included in a semiconductor device according to another embodiment. FIG. 15 illustrates a portion corresponding to FIG. 3.

Referring to FIG. 15, a second pattern 314 included in a pattern layer 310 of a bonding layer may have an island shape. For example, a plurality of second patterns 314 may be spaced apart from each other with a regular interval in each of a first direction (an X-axis direction in the drawings) and a second direction (a Y-axis direction in the drawings). When the second pattern 314 may have the island shape, the second patterns 314 may be disposed uniformly and a heat dissipation path by the second patterns 314 may be uniformly provided.

In FIG. 15, it is illustrated as an example that the second pattern 314 has an enclosed shape (e.g., a rectangular shape). However, the embodiments are not limited thereto, and the second pattern 314 may have any of various shapes, such as a circular shape, an oval shape, a polygonal shape other than a rectangular shape, an irregular shape, or so on.

In FIG. 15, it is illustrated as an example that the plurality of second patterns 314 are disposed at a same position in each of the first direction (the X-axis direction in the drawings) and the second direction (the Y-axis direction in the drawings). However, the embodiments are not limited thereto. As illustrated in FIG. 16, a position of a second pattern 314 (e.g., a position of the second pattern 314 in the second direction) in a first column and a position of the second pattern 314 (e.g., a position of the second pattern 314 in the second direction) in a second column may be different from each other. Each of the first column and the second column may extend in the second direction and the first column and the second column may be adjacent to each other in the first direction. In some embodiments, a position of a plurality of second patterns 314 may be variously modified.

FIG. 17 is a plan view that illustrates a portion of a pattern layer of a bonding layer included in a semiconductor device according to another embodiment. FIG. 17 illustrates a portion corresponding to FIG. 3.

Referring to FIG. 17, a second pattern 314 included in a pattern layer 310 of a bonding layer may have a mesh shape. For example, a plurality of first patterns 312 may be spaced apart from each other with a regular interval in each of a first direction (an X-axis direction in the drawings) and a second direction (a Y-axis direction in the drawings), and the second pattern 314 may be disposed on an entire portion other than the plurality of first patterns 312. The second pattern 314 may be a single portion disposed in a portion where the plurality of first patterns 312 are not disposed. For example, the second pattern 314 may include a plurality of portions extending in the first direction and a plurality of portions extending in the second direction. When the second pattern 314 may have the mesh shape, the second patterns 314 may be disposed to have a large area and a heat dissipation path by the second patterns 314 may be uniformly provided.

In FIG. 17, it is illustrated as an example that the first pattern 312 has an enclosed shape (e.g., a rectangular shape). However, the embodiments are not limited thereto, and the first pattern 312 may have any of various shapes, such as a circular shape, an oval shape, a polygonal shape other than a rectangular shape, an irregular shape, or so on. In FIG. 17, it is illustrated as an example that the plurality of first patterns 312 are disposed at a same position in each of the first direction (the X-axis direction in the drawings) and the second direction (the Y-axis direction in the drawings). However, the embodiments are not limited thereto. In some embodiments, a position of the first pattern 312 (e.g., a position of the first pattern 312 in the second direction) in a first column and a position of the first pattern 312 (e.g., a position of the first pattern 312 in the second direction) in a second column may be different from each other. Each of the first column and the second column may extend in the second direction and the first column and the second column may be adjacent to each other in the first direction.

A shape, a position, or so on of the plurality of first patterns 312 may be variously modified, and a shape, a position, or so on of the second pattern 314 may be variously modified.

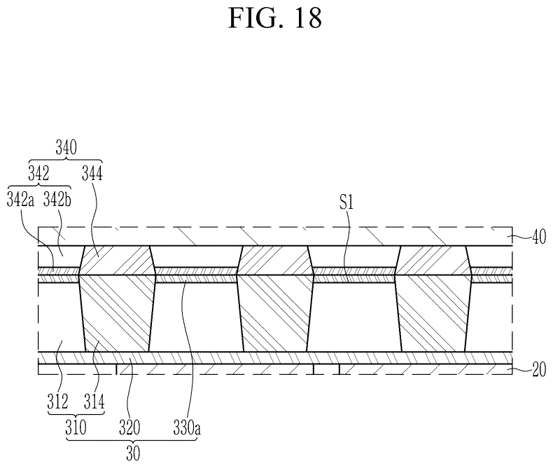

FIG. 18 is a cross-sectional view that illustrates a partial portion of a semiconductor device according to an embodiment. FIG. 18 illustrates a portion corresponding to FIG. 3.

Referring to FIG. 18, a bonding layer 30 according to an embodiment may include a pattern layer 310, a first insulation layer 320, a second insulation layer 330a, and an additional pattern layer 340. The pattern layer 310 may include a first pattern 312 and a second pattern 314. The first insulation layer 320 may be disposed between a first wiring portion 20 and the pattern layer 310. The second insulation layer 330 may be disposed at a periphery (e.g., edge, end, or side) of the second pattern 314 on a second surface S1 of the first pattern 312 that is adjacent to a support substrate 40. The additional pattern layer 340 may be disposed between the pattern layer 310 and the support substrate 40 and between the second insulation layer 330a and the support substrate 40. The additional pattern layer 340 may include an insulation portion 342 and a conductive portion 344. The insulation portion 342 may be disposed between the support substrate 40 and the second insulation layer 330a that is disposed on the first pattern 312. The conductive portion 344 may be disposed between the second pattern 314 and the support substrate 40.

In an embodiment, the pattern layer 310 and the second insulation layer 330a may be bonded to the additional pattern layer 340 by hybrid bonding including insulation-layer bonding and conductive bonding (e.g., metal bonding).

For example, the insulation portion 342 of the additional pattern layer 340 may include a first insulation portion 342a and a second insulation portion 342b. The second insulation portion 342b may include a material different from a material of the first insulation portion 342a. The first insulation portion 342a may be a bonding insulation layer that is disposed at a side of a first surface that is adjacent to the pattern layer 310 and/or the second insulation layer 330a.

In an embodiment, the first insulation portion 342a and the second insulation portion 342b of the additional pattern layer 340a may include materials, structures, shapes, or so on that correspond to the second insulation layer 330a and the first pattern 312, respectively. Therefore, the additional pattern layer 340 may be formed by using a process having a same or similar process condition of a process of forming the pattern layer 310 and the second insulation layer 330a. Accordingly, a process may be simplified.

In FIG. 18, it is illustrated as an example that a thickness of the additional pattern layer 340 is less than a thickness of the second pattern 314 or a sum of a thickness of the first pattern 312 and a thickness of the second insulation layer 330a. Therefore, in the case that includes the additional pattern layer 340, a heat dissipation path may be reduced. However, the embodiments are not limited thereto, and the thickness of the additional pattern layer 340 may be the same as or greater than the thickness of the second pattern 314 or the sum of the thickness of the first pattern 312 and the thickness of the second insulation layer 330a.

Each of the second insulation layer 330a and the first insulation portion 342a of the additional pattern layer 340a may be a bonding insulation layer configured to physically and structurally bond the pattern layer 310 and the support substrate 40 between the pattern layer 310 and the support substrate 40. The second insulation layer 330a may be a first insulation bonding portion that is disposed on the pattern layer 310 (e.g., on the first pattern 312), and the first insulation portion 342a of the additional pattern layer 340a may be a second insulation bonding portion that is disposed on the support substrate 40. The second insulation layer 330a that is the first insulation bonding portion and the first insulation portion 342a of the additional pattern layer 340a that is the second insulation bonding portion may be bonded to each other to form insulation layer bonding.

In an embodiment, the second insulation layer 330a and/or the first insulation portion 342a may include or be formed of a material of oxide, nitride, or carbide. For example, the second insulation layer 330a and/or the first insulation portion 342a may include or be formed of at least one of silicon oxide (SiOx), silicon nitride (SiNx), silicon carbonitride (SiCNx), silicon oxycarbide (SiOCx), silicon oxynitride (SiONx), silicon oxycarbonitride (SiOCNx), or aluminum nitride (AlNx). In an embodiment, the second insulation layer 330a and the first insulation portion 342a may include a same material, for example, silicon carbonitride (SiCNx). However, the embodiments are not limited to a material of the second insulation layer 330a and/or the first insulation portion 342a.

The second insulation portion 342b may include or be formed of oxide, nitride, oxynitride, or so on. For example, the second insulation portion 342b may include or be formed of silicon oxide (SiOx), silicon nitride (SiNx), silicon oxynitride (SiONx), or so on. The second insulation portion 342b may include a material same as a material of the first pattern 312. However, the embodiments are not limited thereto, and the second insulation portion 342b may include a material different from a material of the first pattern 312.

The second pattern 314 and the conductive portion 344 of the additional pattern layer 340 may be a bonding conductive layer (e.g., a bonding metal layer) configured to physically and structurally bond the pattern layer 310 and the support substrate 40 between the pattern layer 310 and the support substrate 40. The second pattern 314 may be a first conductive bonding portion that is included in the pattern layer 310, and the conductive portion 344 of the additional pattern layer 340 may be a second conductive bonding portion that is disposed on the support substrate 40. The second pattern 314 that is the first conductive bonding portion and the conductive portion 344 of the additional pattern layer 340 that is the second conductive bonding portion may be bonded to each other to form conductive bonding (e.g., metal bonding).

In a plan view, the conductive portion 344 may at least partially overlap the second pattern 314 (e.g., in the Z-axis direction). For example, in a plan view, the conductive portion 344 may be disposed at a position same as a position of the second pattern 314 and may have a planar shape substantially same as a planar shape of the second pattern 314. Therefore, the conductive bonding (e.g., the metal bonding) formed by using the second pattern 314 and the conductive portion 344 may be stably formed.

In a cross-sectional view, a side surface of the conductive portion 344 may have an inclined surface so that a width of the conductive portion 344 decrease toward the support substrate 40. This may be because an etching process may be performed at a surface opposite to the support substrate 40 in a process of forming an opening for the conductive portion 344. Accordingly, the side surface of the second pattern 314 and a side surface of the conductive portion 344 may have opposite inclined directions or orientations. However, the embodiments are not limited thereto, and the side surface of the conductive portion 344 may have a vertical surface and the conductive portion 344 may have a substantially uniform width. Various other modifications are possible.

The conductive portion 344 of the additional pattern layer 340 that includes the conductive material may include or be formed of metal. For example, the conductive portion 344 may include or be formed of at least one of copper, aluminum, tungsten, molybdenum, titanium, tantalum, nickel, gold, tin, manganese, or cobalt, or may include or be formed of an alloy that includes the above material. When the conductive portion 344 includes the conductive material (e.g., the metal or the metal alloy), the conductive portion 344 may have relatively high thermal conductivity. In an embodiment, the second pattern 314 and the conductive portion 344 may include a same material, for example, copper. However, the embodiments are not limited thereto.

The pattern layer 310 and the second insulation layer 330a may be stably bonded to the additional pattern layer 340 that is provided with the support substrate 40 by hybrid bonding. The second pattern 314 may be connected to the support substrate 40 through the conductive portion 344 of the additional pattern layer 340 connected to (e.g., directly connected to) the support substrate 40. That is, heat dissipation in a direction toward the support substrate 40 may be effectively achieved through the conductive portion 344 of the additional pattern layer 340 that is connected to (e.g., directly connected to) the support substrate 40.

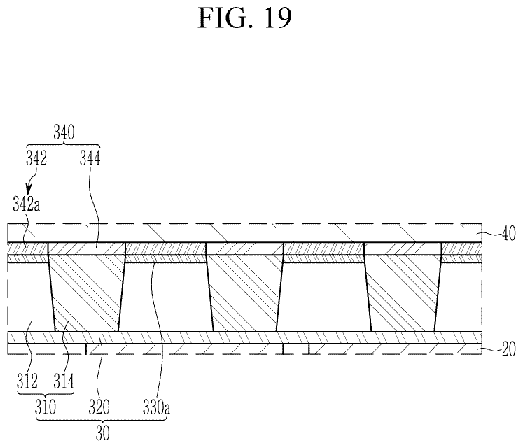

In FIG. 18 and its description, it is illustrated and described as an example that the insulation portion 342 of the additional pattern layer 340 includes the first insulation portion 342a and the second insulation portion 342b. In some embodiments, as illustrated in FIG. 19, an insulation portion 342 of the additional pattern layer 340 may include a first insulation portion 342a and might not include a second insulation portion 342b (refer to FIG. 18). That is, the insulation portion 342 of the additional pattern layer 340 may be formed of the first insulation portion 342a that includes a material same as a material of the second insulation layer 330a. Therefore, a thickness of the additional pattern layer 340 may be reduced more and heat dissipation path may be reduced more. Various other modifications are possible.

While some examples have been described in connection with what is presently considered to be some practical embodiments, it is to be understood that the disclosure is not limited to the disclosed embodiments, and that that the disclosure is intended to cover various modifications and equivalent arrangements included within the scope of the appended claims.

What is claimed is:

1. A semiconductor device, comprising:
a semiconductor element portion that comprises a semiconductor element;
a first wiring portion that is on a first surface of the semiconductor element portion;
a support substrate that is on the first wiring portion;
a bonding layer that is between the first wiring portion and the support substrate; and
a second wiring portion that is on a second surface of the semiconductor element portion opposite to the first surface of the semiconductor element portion,
wherein the bonding layer comprises a pattern layer,
wherein the pattern layer comprises a first pattern that comprises an insulating material and a second pattern that has a thermal conductivity greater than a thermal conductivity of the first pattern and is electrically insulated from the first wiring portion.

2. The semiconductor device of claim 1, wherein the second pattern comprises a conductive material.

3. The semiconductor device of claim 2, wherein the second pattern comprises a metal or a metal alloy.

4. The semiconductor device of claim 1, wherein the first pattern and the second pattern at least partially overlap each other in a first direction that is parallel to a first surface of the support substrate.

5. The semiconductor device of claim 1, further comprising:
a first insulation layer that is between the second pattern and the first wiring portion and electrically insulates the second pattern and the first wiring portion from each other.

6. The semiconductor device of claim 5, wherein the first insulation layer comprises an insulating material different from the insulating material of the first pattern.

7. The semiconductor device of claim 1, wherein, in a plan view, the second pattern has a linear shape or an enclosed shape.

8. The semiconductor device of claim 1, wherein, in a plan view, an area of the first pattern is greater than an area of the second pattern; or
wherein a ratio of a width of the second pattern to a thickness of the second pattern is 0.5 or more.

9. The semiconductor device of claim 1, wherein at least a portion of a second surface of the second pattern that is adjacent to the support substrate extends further toward the support substrate in a first direction that is perpendicular to a first surface of the support substrate than a second surface of the first pattern that is adjacent to the support substrate; or
wherein a step is at a boundary of the second surface of the second pattern and the second surface of the first pattern; or
wherein the second surface of the second pattern has a convex shape extending toward the support substrate, and the second surface of the first pattern has a concave shape.

10. The semiconductor device of claim 1, further comprising:
a first insulation layer that is between the pattern layer and the first wiring portion; and
a second insulation layer that is between the pattern layer and the support substrate.

11. The semiconductor device of claim 10, wherein the first insulation layer and the second insulation layer comprise a same material.

12. The semiconductor device of claim 10, wherein the first insulation layer has a dielectric constant that is less than a dielectric constant of the first pattern or a dielectric constant of the second insulation layer.

13. The semiconductor device of claim 1, further comprising:
a first insulation layer that is between the pattern layer and the first wiring portion;
a second insulation layer that is on a periphery of the second pattern and is on a second surface of the first pattern adjacent to the support substrate; and
an additional pattern layer that comprises an insulation portion between the second insulation layer and the support substrate and a conductive portion between the second pattern and the support substrate.

14. The semiconductor device of claim 13, wherein the insulation portion of the additional pattern layer comprises a first insulation portion that comprises a material same as a material of the second insulation layer; or
wherein the insulation portion of the additional pattern layer comprises a second insulation portion that comprises a material different from a material of the first insulation portion.

15. The semiconductor device of claim 1, wherein the semiconductor element comprises:
an active region that includes a plurality of channel layers spaced apart from each other in a direction that is perpendicular to a first surface of the support substrate;
a gate structure that includes a gate electrode at least partially surrounding each of the plurality of channel layers and a gate insulation layer between the plurality of channel layers and the gate electrode; and
source and drain patterns that are on opposing sides of the active region.

16. A semiconductor device, comprising:
a semiconductor element portion that comprises a semiconductor element;
a first wiring portion that is on a first surface of the semiconductor element portion;
a support substrate that is on the first wiring portion;
a bonding layer that is between the first wiring portion and the support substrate; and
a second wiring portion that is on a second surface of the semiconductor element portion opposite to the first surface of the semiconductor element portion,
wherein the bonding layer comprises a first insulation layer that is on the first wiring portion and a conductive pattern that is on the first insulation layer.

17. The semiconductor device of claim 16, wherein the conductive pattern at least partially overlaps the first insulation layer in a first direction that is perpendicular to a first surface of the support substrate.

18. The semiconductor device of claim 16, wherein the bonding layer further comprises an insulation pattern that on a periphery of the conductive pattern.

19. A semiconductor device, comprising:
a semiconductor element portion that comprises a semiconductor element;
a front wiring portion that is on a front surface of the semiconductor element portion;
a support substrate that is on the front wiring portion;
an intermediate layer that is between the front wiring portion and the support substrate; and
a rear wiring portion that is on a rear surface of the semiconductor element portion,
wherein the intermediate layer comprises a pattern layer, and
wherein the pattern layer includes an insulation pattern that comprises an insulating material and a heat dissipation pattern that comprises a conductive material and is electrically insulated from the front wiring portion.

20. The semiconductor device of claim 19, further comprising:
a first insulation layer that is between the heat dissipation pattern and the front wiring portion and electrically insulates the heat dissipation pattern and the front wiring portion from each other.
